(19) United States
(12) Patent Application Publication
(10) Pub. No.: US 2025/0024651 A1
(43) Pub. Date: Jan. 16, 2025

(54) PARALLEL COOLING METHODOLOGIES

(71) Applicant: Vitesco Technologies USA, LLC, Auburn Hills, MI (US)

(72) Inventor: Wai-Tak Ho, Palatine, IL (US)

(73) Assignee: Vitesco Technologies USA, LLC, Auburn Hills, MI (US)

(21) Appl. No.: 18/765,245

(22) Filed: Jul. 6, 2024

Related U.S. Application Data
(60) Provisional application No. 63/513,200, filed on Jul. 12, 2023.

(51) Int. Cl. H05K 7/20

(52) U.S. Cl. CPC H05K 7/209; H05K 7/20436

(57) ABSTRACT

A cooling system having several cooling features for a high-voltage (HV) inverter, which provide more desirable cooling of multiple power modules, and reduce the pressure drop from the inlet to the outlet. The HV inverter includes a separator disposed in the cavity of a housing, where the separator includes several flow apertures which shorten the flow path of at least a portion of coolant fluid from the inlet to the outlet. The combination of the diameter of the flow apertures and location of the flow apertures between the inlet and the heat object location (i.e., one or more power modules), improves/reduces the temperature difference between a first of the power modules and one or more of the power modules which are located further away from the inlet. Also, the location of the flow apertures achieves a shorter distance terminal between the inlet and the outlet, improving the overall pressure drop.

### CROSS-REFERENCE TO RELATED APPLICATIONS

This application claims the benefit of provisional application 65/513,200, filed Jul. 12, 2023. The disclosure of the above application is incorporated herein by reference.

### FIELD OF THE INVENTION

The invention relates generally to at least one cooling feature for a high-voltage inverter, where the cooling feature has various parallel flow paths.

### BACKGROUND OF THE INVENTION

Components in an electric vehicle, such as a high-voltage (HV) inverter, require various cooling systems for desired thermal management. A cooling system has an inlet, an outlet (where the inlet and outlet are part of the housing of the inverter), and a cooling channel area. A heatsink inside the cooling channel area includes a fin design (either pin, long fin, or other geometry shape design) to maximize the surface contact area for coolant fluid heat exchange. Three power modules (with Si chips) laminated on the heatsink, along with other components, generate heat as electronic currents go through the HV inverter. In power operation, there is a heat exchange interface between the heat energy generated by each Si chip and the fluid in the cooling channel area control the temperature of each Si chip and prevent overheating.

The third power module is typically the furthest distance away from the inlet, and therefore typically has the hottest temperature among the three power modules within the system (for example, the temperature difference between the first power module and the third power module may be up to 10° C.). The fluid flow path includes fluid flowing into the inlet, and then flowing past the first power module, the second power module, the third power module, and then flowing out of the outlet. In some cooling channel designs, due to the long distance the fluid travels in the cooling channel between the inlet and the outlet, an undesirable pressure drop between the inlet and outlet may occur. Also, the temperature of the fluid is increased after the heat exchange between the fluid the first power module, and the heat exchange between the fluid and the second power module, resulting in limited cooling of the third power module.

Accordingly, there exists a need for a cooling system which provides more efficient and effective cooling of all power modules in a HV inverter, and also reduces the pressure drop from the inlet to the outlet.

### SUMMARY OF THE INVENTION

The present invention is several cooling features for a high-voltage (HV) inverter, which provides more desirable cooling of multiple power modules, and reduces the pressure drop from the inlet to the outlet.

In an embodiment, the HV inverter includes a separator disposed in the cavity of a housing, where the separator includes several flow apertures which shorten the flow path of at least a portion of coolant fluid from the inlet to the outlet. The combination of the diameter of the flow apertures and location of the flow apertures between the inlet and the heat object location (i.e., one or more power modules), improves/reduces the temperature difference between a first of the power modules and one or more of the power modules which are located further away from the inlet. Also, the location of the flow apertures achieves a shorter distance between the inlet, the heat exchange area, and the outlet, improving the overall pressure drop.

The HV inverter having the cooling features of the present invention achieves a desired heat exchange environment, a more desirable pressure drop between the inlet and outlet of the housing, and maintains the coolant entry fluid temperature and flow rate. The HV inverter having the cooling features of the present invention maintains the temperature of the coolant each power module is exposed to equal or as close as the fluid inlet terminal temperature. Also, a shorter distance between the inlet and outlet reduces the pressure drop from the inlet to the outlet.

In an embodiment, the present invention is a high voltage (HV) inverter having a cooling system, having a housing, a separator disposed in the housing, at least one flow aperture integrally formed as part of the separator, a heat sink connected to the separator and located in the housing, a plurality of power modules mounted to the heat sink, and a plurality of heat transfer areas which are part of the heat sink, each of the plurality of power modules mounted to the heat sink in one of the plurality of heat transfer areas. The cooling system also includes a first flow area located on a first side of the separator and a second flow area on a second side of the separator, in between the separator and the heat sink. The cooling system also includes a first flow path, where a first portion of the fluid flows along the first flow area such that the first portion of the fluid flows around an end of the separator and then flows along the second flow area, and a second flow path, where a second portion of the fluid flows along part of the first flow area such that the second portion of the fluid flows through the at least one flow aperture and then flows through part of the second flow area. The first portion of fluid flowing along the first flow path transfers heat away from a first of the plurality of power modules, and the second portion of the fluid flowing along the second flow path and transfers heat away from a second of the plurality of power modules.

The HV inverter also includes a base portion being part of the heat sink, a plurality of pins integrally formed as part of the base portion, and a plurality of receiving apertures integrally formed as part of the separator. A part of each of the plurality of pins extends into a corresponding one of the plurality of receiving apertures such that a portion of each of the plurality of pins is disposed between the base portion and the separator, and the second flow area includes flow around one or more of the portion of each of the plurality of pins disposed between the base portion and the separator.

In an embodiment, a plurality of flow apertures are integrally formed as part of the separator.

In an embodiment, a first portion of the flow apertures is part of the second flow path, such that the second portion of fluid flows through the first of the flow apertures.

In an embodiment, the present invention includes a third flow path, where a third portion of the fluid flows along part of the first flow area such that the third portion of the fluid flows through a second portion of the plurality of flow apertures and then flows along a portion of the second flow area, transferring heat away from a third of the power modules.

In an embodiment, at least two of the apertures are part of the second flow path, and at least two of the apertures are part of the third flow path.

In an embodiment, the diameter of each of the second portion of the plurality of flow apertures is different compared to the diameter of each of the first portion of the plurality of flow apertures.

In an embodiment, an inlet is integrally formed as part of the housing, and an outlet integrally formed as part of the housing. The inlet is in fluid communication with the first flow area, and the outlet is in fluid communication with the second flow area.

In an embodiment, the flow aperture includes an angled inlet portion having an angled sidewall, a central aperture having a sidewall, the central aperture integrally formed with the angled inlet portion, and an angled outlet portion having an angled sidewall. The angled outlet portion is integrally formed with the central aperture, on the opposite side of the central aperture relative to the angled inlet portion. The angled inlet portion is in fluid communication with the first flow area, and the angled outlet portion is in fluid communication with the second flow area.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a first exploded view of an HV inverter having at least one cooling feature, according to embodiments of the present invention;

FIG. 2 is a second exploded view of an HV inverter having at least one cooling feature, according to embodiments of the present invention;

FIG. 3 is an exploded view of a cooling plate and several power modules which are part of an HV inverter having at least one cooling feature, according to embodiments of the present invention;

FIG. 4 is a perspective view a body of fluid which flows through an HV inverter, and a cooler plate which is part of an HV inverter having at least one cooling feature, according to embodiments of the present invention;

FIG. 5 is a perspective view of a separator and a cooling plate which are part of an HV inverter having at least one cooling feature, according to embodiments of the present invention;

FIG. 6 is side view of a body of fluid which flows through an HV inverter having at least one cooling feature, according to embodiments of the present invention;

FIG. 7 is a perspective view of a cooler plate with thermal analysis, where the cooler plate which is part of an HV inverter having at least one cooling feature, according to embodiments of the present invention;

FIG. 8 is a perspective view of an alternate embodiment of a separator and a cooling plate which are part of an HV inverter having at least one cooling feature, according to embodiments of the present invention;

FIG. 9 is a sectional view of a portion of another alternate embodiment of an HV inverter, according to embodiments of the present invention;

FIG. 10 is an enlarged view of section 10 in FIG. 9;

FIG. 11 is an enlarged view of section 11 in FIG. 10;

FIG. 12 is an enlarged view of section 12 in FIG. 10;

FIG. 13 is a bottom view of a separator used as part of the HV inverter shown in FIG. 9, according to embodiments of the present invention;

FIG. 14 is an enlarged view of a portion of FIG. 13.

### DETAILED DESCRIPTION OF THE PREFERRED EMBODIMENTS

The following description of the preferred embodiment(s) is merely exemplary in nature and is in no way intended to limit the invention, its application, or uses.

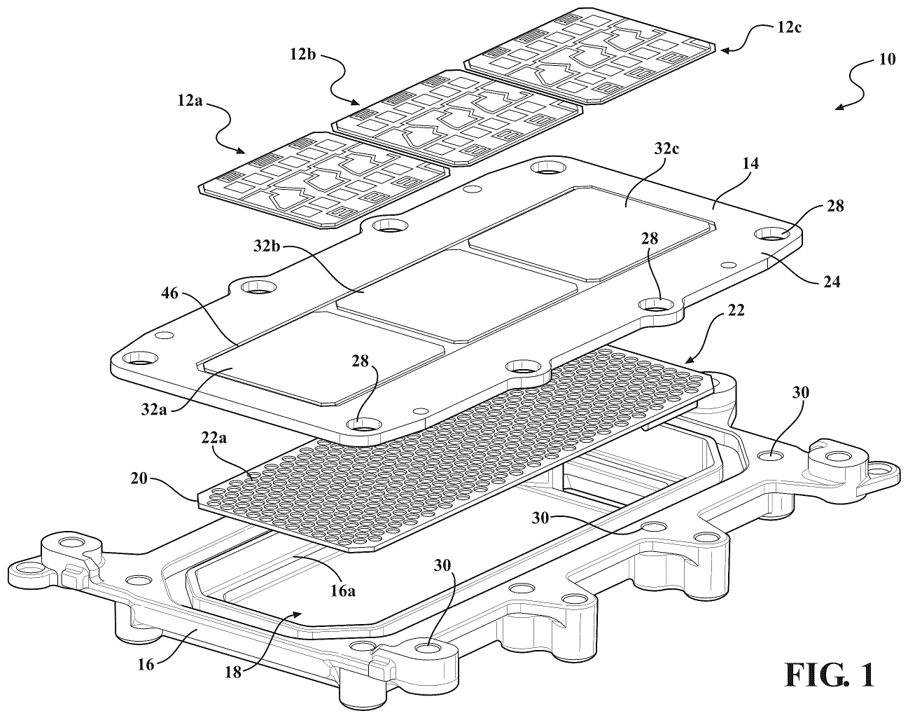

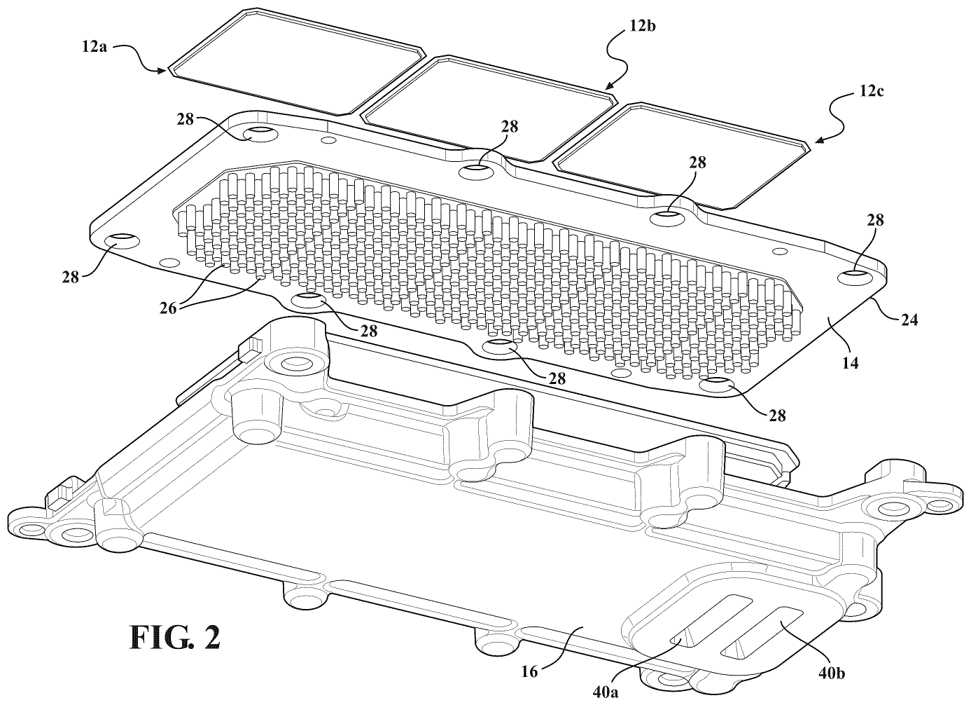

A high-voltage (HV) inverter having one or more cooling features according to the present invention is shown in FIGS. 1-2, generally at 10. The HV inverter 10 includes a first power module, shown generally at 12a, a second power module, shown generally at 12b, and a third power module, shown generally at 12c. The power modules 12a, 12b, 12c are mounted to a heat sink, which in this embodiment is a cooler plate 14.

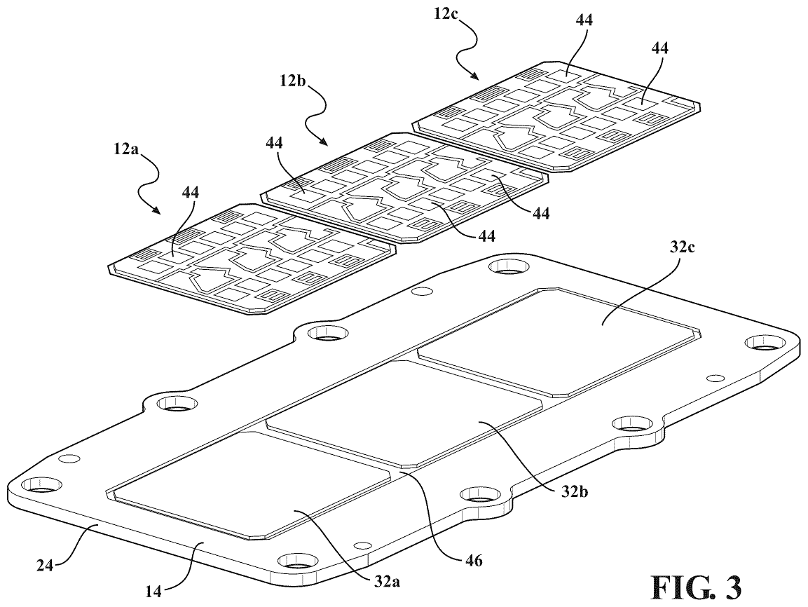

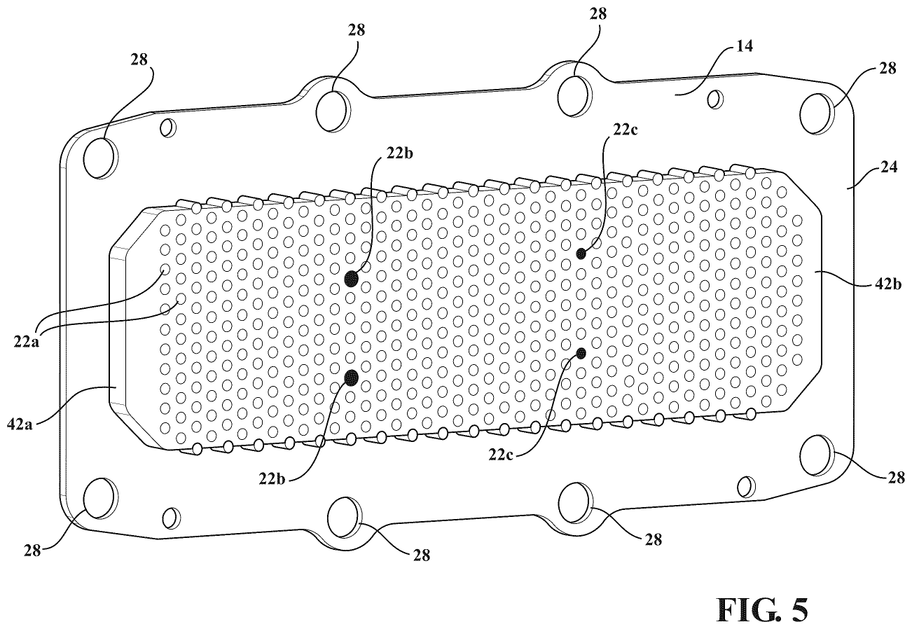

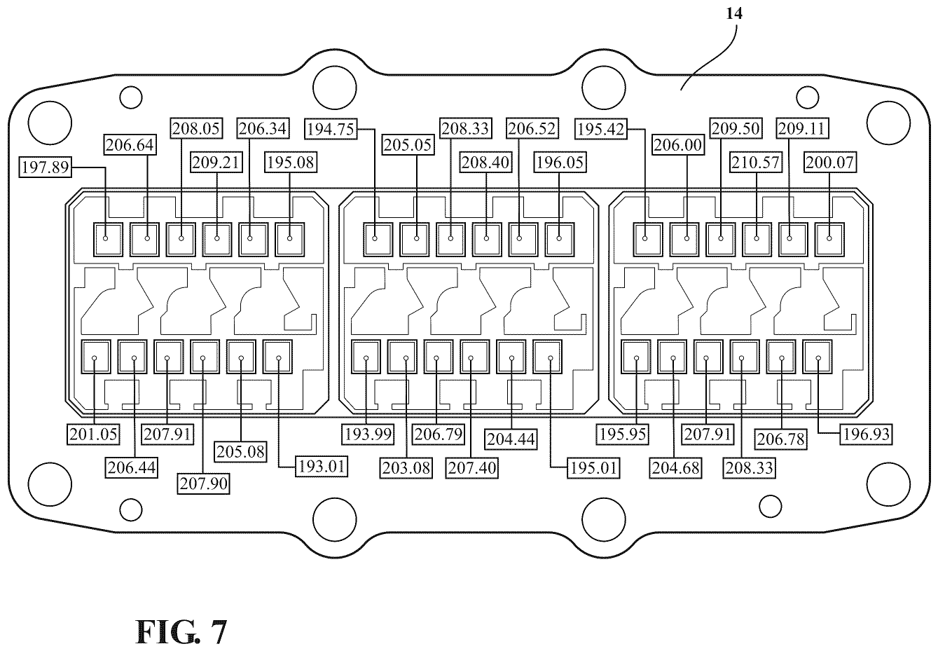

The HV inverter 10 also includes a housing 16, and the housing 16 has a cavity, shown generally at 18. Disposed in the cavity 18 is a separator 20. The separator 20 has a plurality of apertures, shown generally at 22. More specifically and with reference to FIGS. 1-2 and 5, the separator 20 has receiving apertures 22a and at least one flow aperture 22b,22c, and the embodiment shown in FIGS. 1-7 has four flow apertures 22b,22c. The cooler plate 14 has a base portion 24, and integrally formed with the base portion 24 is a plurality of pins, several of which are referenced at 26. When assembled, each of the pins 26 are received into a corresponding one of the plurality of receiving apertures 22a. To assemble the cooler plate 14 to the housing 16, fasteners (not shown) are inserted through fastening apertures 28 of the cooler plate 14 and into fastening apertures 30 of the housing 16, which encloses the cavity 18, such that the separator 20 is disposed in the cavity 18. When the separator 20 is disposed in the cavity 18, the separator 20 is supported by an edge portion 16a located in the cavity 18 of the housing 16.

The power modules 12a, 12b, 12c are mounted to corresponding mounting areas 32a,32b,32c, where each of the mounting areas 32a,32b,32c is surrounded by a portion of a disconnecting circuit breaker (DCB) groove 46, which is integrally formed as part of the base portion 24 of the cooler plate 14.

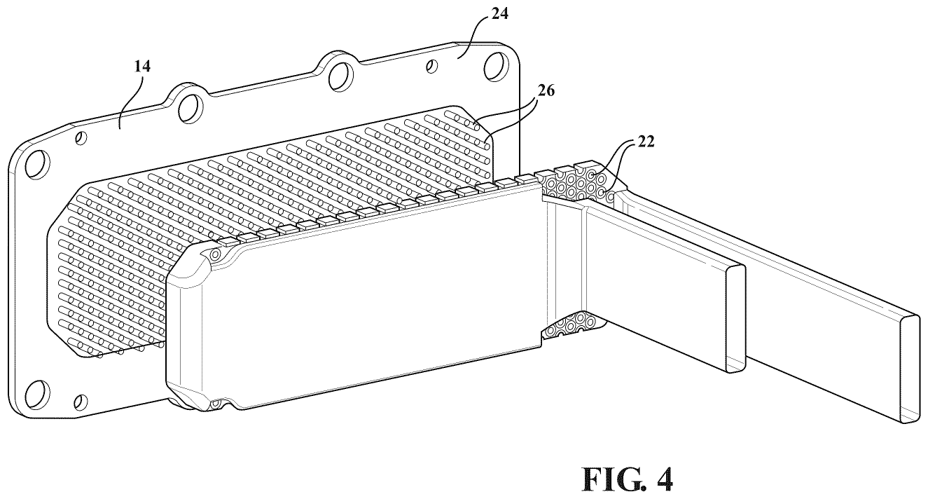

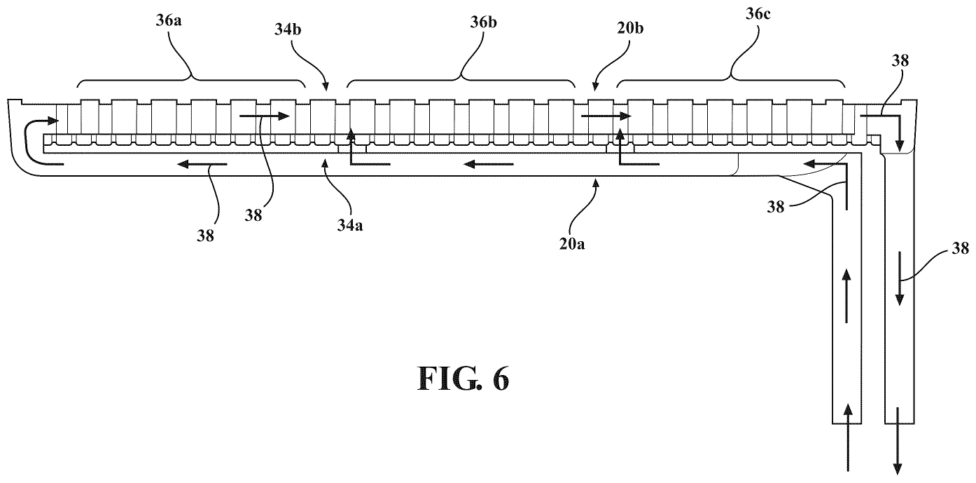

The body of coolant which flows through the HV inverter is shown in FIG. 6, and with reference to FIGS. 4-6, once assembled, the separator 20 divides the cavity 18 into two flow areas. There is a first flow area, shown generally at 34a, on a first side, shown generally at 20a, of the separator 20, and a second flow area, shown generally at 34b, on a second side, shown generally at 20b, of the separator 20.

Referring to FIGS. 1-7 generally, during operation, each of the power modules 12a, 12b, 12c generates heat, and the coolant flowing through the HV inverter 10 is used to cool the power modules 12a, 12b, 12c. The power modules 12a, 12b, 12c have chips, several of which are labeled at 44, where the chips 44 closest to the center of the power module 12a, 12b, 12c have the highest temperature during operation. Each power module 12a, 12b, 12c has an area where heat is exchanged to control the temperature of each of the power modules 12a, 12b, 12c. More specifically, there is a first heat transfer area, shown generally at 36a, a second heat transfer area, shown generally at 36b, and a third heat transfer area, shown generally 36c, where heat is transferred away from the power modules 12a, 12b, 12c, respectively.

The flow path of the coolant through the HV inverter 10 is indicated by the arrows 38. The fluid flows into the inlet 40a of the housing 16 and into the first flow area 34a. A portion of the fluid in the first flow area 34a flows around a first end portion 42a of the separator 20 and into the second flow area 34b. However, a second portion of the fluid in the first flow area 34a flows through the flow apertures 22b into the second flow area 34b, and a third portion of the fluid in the first flow area 34a flows through the flow apertures 22c into the second flow area 34b.

The first portion of the fluid flows around the first end portion 42a into the second flow area 34b, and then flows through the first heat transfer area 36a and cools the first power module 12a. The first portion of the fluid then flows through the second heat transfer area 36b, cooling the second power module 12b, and then flows through the third heat transfer area 36c, cooling the third power module 12c. However, after the first portion of fluid flows through the first heat transfer area 36a, the temperature of the first portion of fluid has increased, limiting the cooling effect on the second power module 12b as the first portion of fluid flows through the second heat transfer area 36b. The temperature of the first portion of fluid is further increased after flowing through the second heat transfer area 36b, further limiting the cooling effect on the third power module 12c as the first portion of fluid flows through the third heat transfer area 36c. After flowing through the third heat transfer area 36c, the first portion of fluid flows through the outlet 40b.

The second portion of fluid flows through the flow apertures 22b into the second flow area 34b, and then flows through the second heat transfer area 36b and cools the second power module 12b. The second portion of fluid then flows through the third heat transfer area 36c, cooling the third power module 12c. However, after the second portion of fluid flows through the second heat transfer area 36b, the temperature of the second portion of fluid has increased, limiting the cooling effect on the third power module 12c as the second portion of fluid flows through the third heat transfer area 36c. After flowing through the third heat transfer area 36c, the second portion of fluid flows through the outlet 40b.

The third portion of fluid flows through the flow apertures 22c into the third flow area 34c, and then flows through the third heat transfer area 36c and cools the third power module 12c. After flowing through the third heat transfer area 36c, the third portion of fluid flows through the outlet 40b.

The flow apertures 22b,22c are apertures of the separator 20 which are unoccupied by the pins 26. The second portion of fluid flowing through the flow apertures 22b is not exposed to the heat from the first heat transfer area 36a, and therefore the second portion of fluid provides more effective cooling of the second power module 12b than the first portion of fluid. The third portion of fluid flowing through the flow apertures 22c is not exposed to heat from the first heat transfer area 36a or the second heat transfer area 36b, and therefore the third portion of fluid provides more effective cooling of the third power module 12c than the first portion of fluid and the second portion of fluid. Although there are different flow paths, the first portion of fluid, the second portion of fluid, and the third portion of fluid enter the second flow area 34b at approximately the same temperature.

In the embodiment shown, the flow apertures 22b have a different diameter than the flow apertures 22c. In this embodiment, the flow apertures 22b have a diameter of 3.56 mm, and the flow apertures 22c have a diameter of 2.54 mm. However, it is within the scope of the invention that the diameter of the flow apertures 22b,22c may be varied to suit any application. The location of the flow apertures 22b allows the second portion of fluid to have a different flow path than the first portion of fluid. The second portion of fluid has a shorter flow path from the inlet 40a to the outlet 40b compared to the first portion of fluid and a longer flow path from the inlet 40a to the outlet 40b compared to the third portion of fluid. Similarly, the third portion of fluid has a shorter flow path from the inlet 40a to the outlet 40b compared to the first portion of fluid and the second portion of fluid. The shortened flow path for the second portion of fluid and the third portion of fluid also reduces the pressure drop from the inlet 40a to the outlet 40b. If the flow rate from the inlet 40a into the first flow area 34a is increased, the pressure in the first flow area 34a is increased as well, and larger volumes of fluid flow through the apertures 22b,22c. The apertures 22b,22c allow for an increase in flow rate through the heat transfer areas 36b,36c, decreasing the pressure drop between the inlet 40a and the outlet 40b. In other embodiments, additional pins 26 may be removed, such that there are additional apertures similar to the apertures 22b,22c, which increases the volume and/or flow rate of the second portion of fluid, as well as the volume and/or flow rate of the third portion of fluid in the heat transfer areas 36b,36c, which then increases the fluid flow from the first flow area 34a to the second flow area 34b and to the outlet 40b.

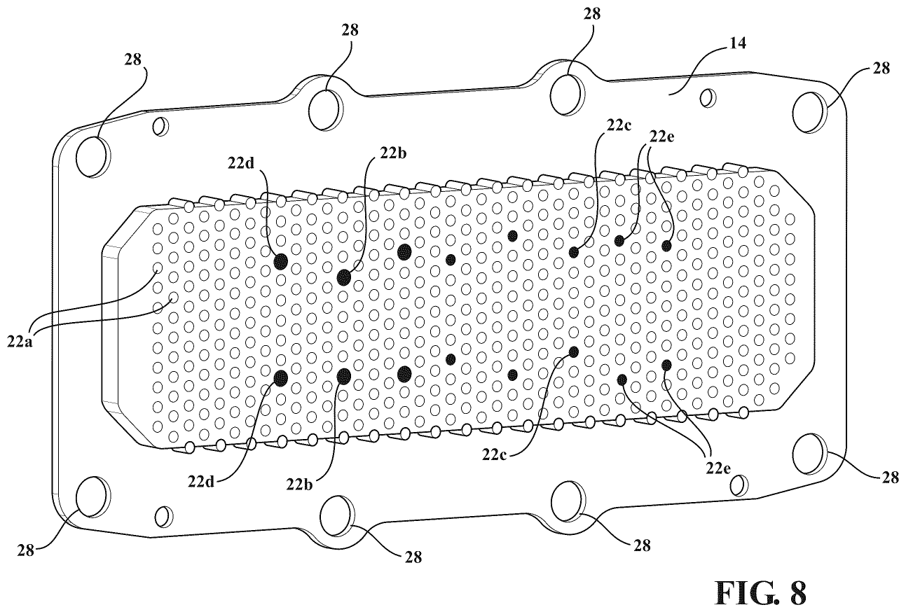

An alternate embodiment of the invention is shown in FIG. 8, with like numbers referring to like elements. In the embodiment shown in FIG. 8, there are additional flow apertures 22d,22e. The flow apertures 22d are approximately the same diameter as the flow apertures 22b, and the flow apertures 22e are approximately the same diameter as the flow apertures 22c. However, it is within the scope of the invention that the apertures 22d,22e may be changed to suit any specific application, and provide desired cooling. The additional flow apertures 22d,22e provide additional flow paths, and achieve desired cooling of the power modules 12a, 12b, 12c. The additional apertures 22d,22e may be necessary to accommodate a variation of the HV inverter 10 having a higher voltage chip set and layout design. Additional apertures may be added, similar to the apertures 22d,22e, where the apertures are sized in proportion and scale to maintain the desired functionality and fluid flow through the HV inverter 10. Proper size and location of any additional apertures 22d,22e facilitates efficient operation of the system.

The cooling features of the present invention provide desired cooling to the HV inverter 10, and also reduce the pressure drop from the inlet 40a to the outlet 40b. More or less flow apertures 22b,22c,22d,22e may be used to provide desired portions of fluid flowing through the flow areas 34a,34b,34c.

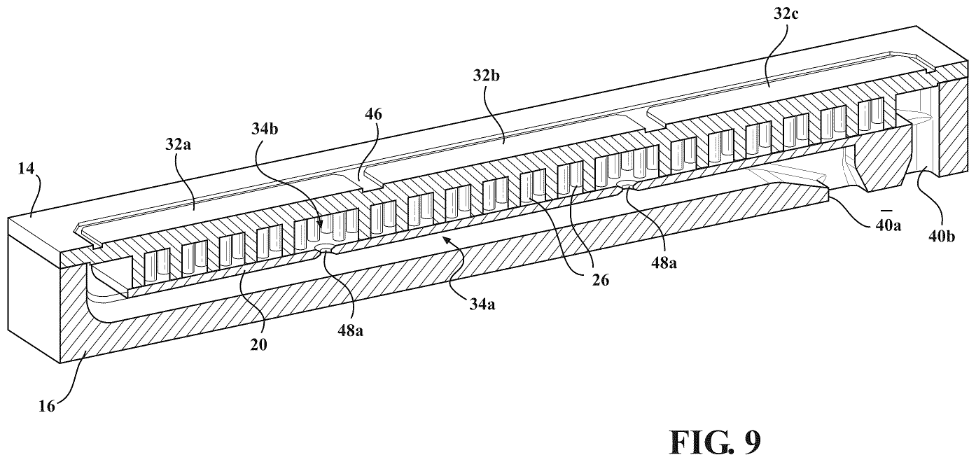

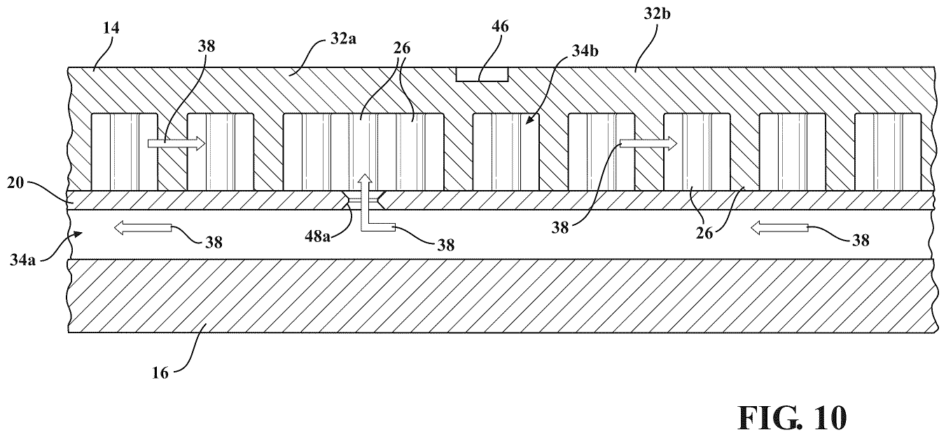

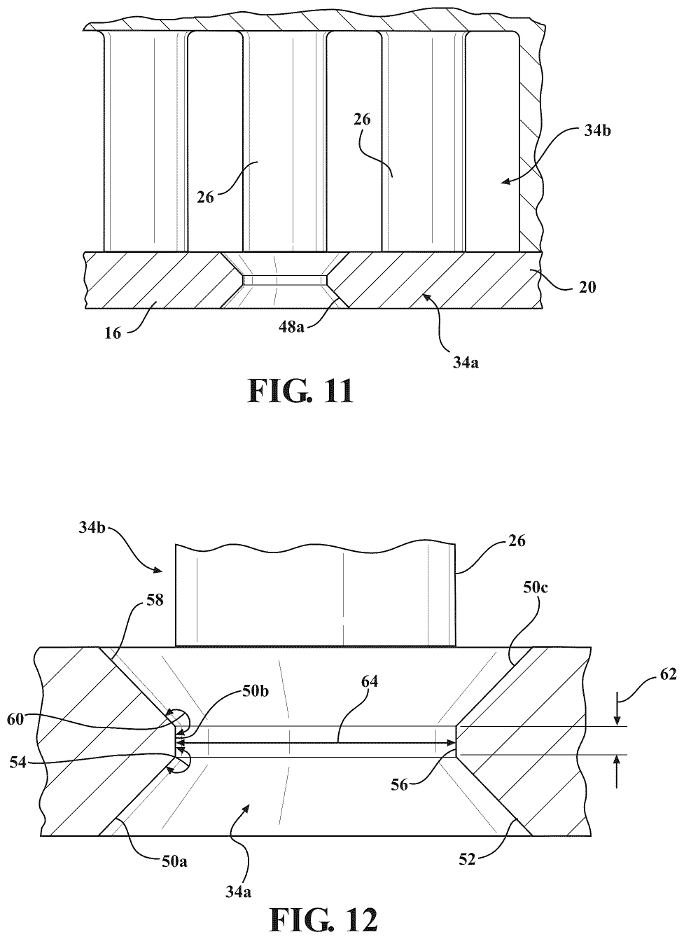

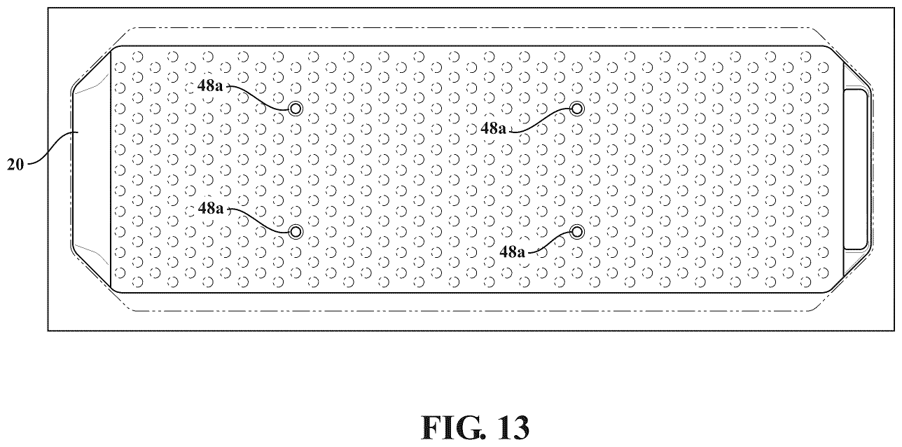

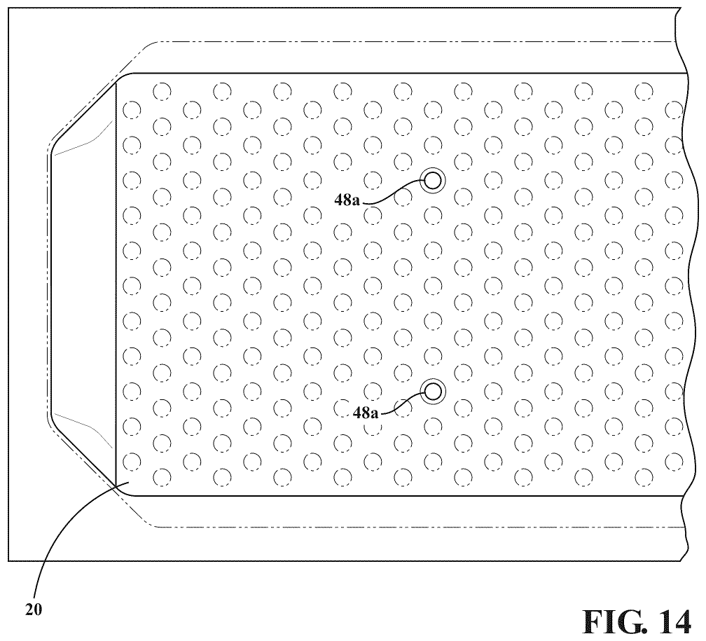

Another alternate embodiment of the present invention is shown in FIGS. 9-14, with like numbers referring to like elements. In this embodiment, the separator 20 still includes the receiving apertures 22a. However, several flow apertures 48a are formed as part of the separator, which are different from the flow apertures 22a,22b,22c,22d,22e.

The flow apertures 48a shown in FIGS. 9-14 are of similar shape. Each flow aperture 48a includes an angled inlet portion 50a, a central aperture 50b, and an angled outlet portion 50c. The angled inlet portion 50a and the angled outlet portion 50c are conically shaped such that the angled inlet portion 50a includes an angled sidewall 52 which is located at an angle 54 relative to a sidewall 56 of the central aperture 50b, and the angled outlet portion 50c includes an angled sidewall 58 which is located at an angle 60 relative to the sidewall 56 of the central aperture 50b. The central aperture 50b is circular shaped, and the height of the sidewall 56 of the central aperture 50b is indicated at 62, and diameter of the central aperture 50b is indicated at 64.

The coolant flows through HV inverter 10 in the embodiment shown in FIGS. 9-14 in a similar manner to the previous embodiment. However, the shape of the flow apertures 48a facilitates the flow rate of the second flow area 34b occupied by the heat transfer areas 36b,36c being higher than the flow rate in the first flow area 34a which also affect the temperature of the heat transfer areas 36b,36c. Additionally, the angles 54,60 of the angled sidewalls 52,58 and the diameter 64 and height 62 of the sidewall 56 may be changed to achieve various flow rates of coolant flowing through the flow areas 34a,34b, which therefore affects the flow of the coolant across the heat transfer areas 36a,36b,36c, and therefore the temperature of the heat transfer areas 36a,36b,36c. By changing the shape of flow apertures 48a, the flow velocity may be increased, and the pressure drop may be reduced before fluid flows into the heat transfer areas 36b,36c. Since fluid flow passes through the heat transfer area 36a, the velocity of the fluid flow is decreased, and fluid pressure drop increases.

In the embodiment shown in FIGS. 9-14, there are a total of four flow apertures 48c shown. In other alternate embodiments, more or less flow apertures 48a may be used to achieve the desired flow rate of coolant flows through the flow areas 34a,34b. In a non-limiting example, the separator 20 may include the same number of flow apertures 48a in the same configuration as shown in FIG. 8, with the flow apertures 48a having different sizes to facilitate the coolant having a desired flow rate.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. An apparatus, comprising:
a cooling system for a high voltage inverter, including:
a separator;
at least one flow aperture integrally formed as part of the separator;
a heat sink located in proximity to the separator;
a plurality of power modules mounted to the heat sink;
a first flow area located on a first side of the separator;
a second flow area on a second side of the separator, in between the separator and the heat sink;
a plurality of heat transfer areas which are part of the heat sink, each of the plurality of power modules mounted to the heat sink in one of the plurality of heat transfer areas; and
a plurality of flow paths, a first of the plurality of flow paths includes a first portion of the fluid flowing through the first flow area, around an end of the separator, and then through the second flow area, and a second of the plurality of flow paths includes a second portion of the fluid flowing along part of the first flow area, through the at least one flow aperture, and then flowing through part of the second flow area;
wherein the first portion of fluid flowing along the first of the plurality of flow paths reduces the temperature of a first and a second of the plurality of heat transfer areas, and the second portion of fluid flowing along the second of the plurality of flow paths reduces the temperature of the second of the plurality of heat transfer areas.

2. The apparatus of claim 1, further comprising:
a base portion being part of the heat sink;
a plurality of pins integrally formed as part of the base portion; and
a plurality of receiving apertures integrally formed as part of the separator;
wherein a part of each of the plurality of pins extends into a corresponding one of the plurality of receiving apertures such that a portion of each of the plurality of pins is disposed between the base portion and the separator, and the second flow area includes flow around one or more of the portion of each of the plurality of pins disposed between the base portion and the separator.

3. The apparatus of claim 1, the at least one flow aperture further comprising a plurality of flow apertures integrally formed as part of the separator, such that at least a first portion of the plurality of apertures are part of the second flow path.

4. The apparatus of claim 3, further comprising
a third flow path;
wherein the third flow path includes a third portion of the fluid flowing through part of the first flow area such that the third portion of the fluid flows through a second portion of the plurality of flow apertures and then flows through part of the second flow area, reducing the temperature of a third of the plurality of heat transfer areas.

5. The apparatus of claim 4, wherein the diameter of each of the second portion of the plurality of flow apertures is different compared to the diameter of each of the first portion of the plurality of flow apertures.

6. The apparatus of claim 1, further comprising:
a housing, the heat sink and the separator located in a cavity of the housing;
an inlet integrally formed as part of the housing; and
an outlet integrally formed as part of the housing;
wherein the inlet is in fluid communication with the first flow area, and the outlet is in fluid communication with the second flow area.

7. The apparatus of claim 1, the at least one flow aperture further comprising:
an angled inlet portion;
a central aperture, the central aperture integrally formed with the angled inlet portion; and
an angled outlet portion, the angled outlet portion integrally formed with the central aperture, on the opposite side of the central aperture relative to the angled inlet portion;
wherein the angled inlet portion is in fluid communication with the first flow area, and the angled outlet portion is in fluid communication with the second flow area.

8. The apparatus of claim 7, the at least one flow aperture further comprising:
a sidewall formed as part of the central aperture;
an angled sidewall integrally formed as part of the angled inlet portion; and
an angled sidewall integrally formed as part of the angled outlet portion;
wherein the flow rate of coolant is increased as a result of flowing through the at least one flow aperture.

9. A high voltage (HV) inverter having a cooling system, comprising:
a housing;
a separator disposed in the housing;
at least one flow aperture integrally formed as part of the separator;
a heat sink connected to the separator and located in the housing;
a plurality of power modules mounted to the heat sink;
a plurality of heat transfer areas which are part of the heat sink, each of the plurality of power modules mounted to the heat sink in one of the plurality of heat transfer areas;
a first flow area located on a first side of the separator;
a second flow area on a second side of the separator, in between the separator and the heat sink;
a first flow path, where a first portion of the fluid flows along the first flow area such that the first portion of the fluid flows around an end of the separator and then flows along the second flow area;
a second flow path, where a second portion of the fluid flows along part of the first flow area such that the second portion of the fluid flows through the at least one flow aperture and then flows through part of the second flow area;
wherein the first portion of fluid flowing along the first flow path transfers heat away from a first of the plurality of power modules, and the second portion of the fluid flowing along the second flow path and transfers heat away from a second of the plurality of power modules.

10. The HV inverter of claim 9, further comprising:
a base portion being part of the heat sink;
a plurality of pins integrally formed as part of the base portion; and
a plurality of receiving apertures integrally formed as part of the separator;
wherein a part of each of the plurality of pins extends into a corresponding one of the plurality of receiving apertures such that a portion of each of the plurality of pins is disposed between the base portion and the separator, and the second flow area includes flow around one or more of the portion of each of the plurality of pins disposed between the base portion and the separator.

11. The HV inverter of claim 9, the at least one flow aperture further comprising a plurality of flow apertures.

12. The HV inverter of claim 11, wherein a first portion of the plurality of flow apertures is part of the second flow path, such that the second portion of fluid flows through the first of the plurality of flow apertures.

13. The HV inverter of claim 12, further comprising a third flow path, wherein a third portion of the fluid flows along part of the first flow area such that the third portion of the fluid flows through a second portion of the plurality of flow apertures and then flows along a portion of the second flow area, transferring heat away from a third of the plurality of power modules.

14. The HV inverter of claim 13, wherein at least two of the plurality of apertures are part of the second flow path, and at least two of the plurality of apertures are part of the third flow path.

15. The HV inverter of claim 13, wherein the diameter of each of the second portion of the plurality of flow apertures is different compared to the diameter of each of the first portion of the plurality of flow apertures.

16. The HV inverter of claim 9, further comprising:
an inlet integrally formed as part of the housing; and
an outlet integrally formed as part of the housing;
wherein the inlet is in fluid communication with the first flow area, and the outlet is in fluid communication with the second flow area.

17. The HV inverter of claim 9, the at least one flow aperture further comprising:
an angled inlet portion having an angled sidewall;
a central aperture having a sidewall, the central aperture integrally formed with the angled inlet portion; and
an angled outlet portion having an angled sidewall, the angled outlet portion integrally formed with the central aperture, on the opposite side of the central aperture relative to the angled inlet portion;
wherein the angled inlet portion is in fluid communication with the first flow area, and the angled outlet portion is in fluid communication with the second flow area.
